(19) United States
(12) Patent Application Publication
(10) Pub. No.: US 2004/0238923 A1
(43) Pub. Date: Dec. 2, 2004

(54) Surface-mount-enhanced lead frame and method for fabricating semiconductor package with the same

(75) Inventors: Te-Haw Lee, Taichung (TW); Kaun-I Cheng, Taichung (TW); Yueh-Chiung Chang, Taichung (TW); Shih-Yao Liu, Taichung (TW); Kun-Ming Huang, Taichung (TW)

Correspondence Address: THE LAW OFFICES OF MIKIO ISHIMARU, 1110 SUNNYVALE-SARATOGA ROAD, SUITE A1, SUNNYVALE, CA, 94087, US

(73) Assignee: SILICONWARE PRECISION INDUSTRIES CO., LTD., Taichung (TW)

(21) Appl. No.: 10/797,971

(22) Filed: Mar. 10, 2004

(30) Foreign Application Priority Data
Mar. 11, 2003 (TW) 092105166

(51) Int. Cl. H01L 23/495

(52) U.S. Cl. 257/670

(57) ABSTRACT

A surface-mount-enhanced lead frame and a method for fabricating a semiconductor package with the lead frame are proposed, wherein a dam bar structure between any two neighboring lead frames of a lead frame module plate is formed with an indentation and at least a solder metal layer is applied on the bottom surface of the lead frame and the indentation. A singulation process is performed along the indentation to separate the lead frame module plate mounted with semiconductor chips and package body into a plurality of packages. Therefore, the indentation and the solder metal layer applied thereon can provide solder paste improved wettability and increased solder surface, while the semiconductor package with the lead frame is mounted on an external device via a surface-mount-technology, so as to prevent problems of signal transmission owing to separation of solder joint from solder open.

### FIELD OF THE INVENTION

The present invention relates to a surface-mount-enhanced lead frame and a method for fabricating the semiconductor package with the same, and in particular, relates to a quad-flat non-leaded (QFN) lead frame structure and the semiconductor package utilizing the lead frame and its manufacturing processes.

### DESCRIPTION OF THE PRIOR ART

Conventional semiconductor packages use lead frames as die pads to enable the formation of semiconductor packages. The lead frame typically comprises a die pad and a plurality of leads formed around the die pad. After the semiconductor chip is bonded on the die pad and electrically connected to the leads via bonding wires, the chip, die pad, bonding wires and the inner part of the leads are encapsulated by a package body to form the semiconductor package with the lead frame.

There are various structures and types of semiconductor packages using a lead frame as the chip carrier, for example, a quad-flat package (QFP), a quad-flat non-leaded package (QFN), a small outline package (SOP), or a dual inline package (DIP) etc. In order to improve the heating dissipation efficiency of the semiconductor package and while meeting the small size requirement of the chip scale package (CSP), the main stream of semiconductor package is a QFN package with exposed die pad.

As disclosed in U.S. Pat. No. 6,143,981, and referring to FIG. 1A, the characteristics of a quad-flat non-leaded (QFN) package 1 is that there are no outwardly extending leads, thereby the size of the package can be reduced. Further, the bottom surface of the die pad 11 and leads 12 of the lead frame 10 of the QFN package 1, are exposed to the die pad package body 15, so that the semiconductor chip 13 bonded to the die pad 11 and electrically connected to the leads 12 via gold wires 14 can effectively dissipate the heat generated by the semiconductor chip 13, and the QFN package 1 can be electrically connected to external devices, for example, a printed circuit board (not shown), directly via the exposed surfaces of leads 12. Therefore, the manufacturing processes can be simplified and the production cost can be reduced.

In order to realize high yield, high capacity, precise automation and reduced cost of the packaging process, conventional the manufacturing process of the QFN package 1 is performed in a batch type by using a lead frame module plate which is formed with a plurality of lead frames 10 in matrix. After performing die bonding, wire bonding, molding and singulation processes to the lead frame module plate, a plurality of semiconductor package can be formed.

Referring to FIG. 1B, since the typical material used for lead frame 10 is metallic copper, and in order to effectively solder the lead frame on the printed circuit board, typically a lead frame is pre-plated with a solder metal layer 16 (for example, palladium Pd) on the surface thereof or, after the molding process has completed, electroplated with the solder metal layer 16 (for example, tin/lead Sn/Pb) on the exposed surface of the lead frame 10. It thus allows the lead frame 10 to be effectively soldered on the printed circuit board. However, during surface mounting, since after the singulation process the lead cutting portions 12a of the leads 12 are directly exposed to the ambient, and are usually not covered by solder metal layer 16, such as palladium or tin/lead, oxidation of the metallic copper occurs easily. It thus causes poor wettability and adhesion between the semiconductor package and the printed circuit board. In addition, the lead frame is soldered on the printed circuit board through only the bottoms of the leads 12 in contact with the solder paste 17. Solder joints of the leads 12 and the printed circuit board may be separated due to bad joints or solder openings, since the surfaces of the leads may wet with insufficient tin. This causes unreliable signal transmission and further affects the reliability of the semiconductor devices.

Referring to FIG. 2, in an attempt to solve the above problems in the prior art, U.S. Pat. No. 6,281,568 and 6,455,356 disclose a bent-upward part 21 formed on the ends of a lead frame 20 after the molding process, so as to provide solder paste with larger soldering area to avoid the said problem of insufficient wettability between the leads and solder paste. However, in this manner, the product size is increased, unfavorable to the miniaturization requirements of semiconductor devices. In addition, special mold is needed to bend the externally exposed leads into bent shapes, this not only increases the material costs, but also the chances of poor quality of the bent part such as the peeling off of the bent part.

### SUMMARY OF THE INVENTION

A primary objective of the present invention is to provide a surface-mount-enhanced lead frame and a method for fabricating a semiconductor package, so as to increase the lead frame soldering area through simple manufacturing processes, which greatly reduces the problems of signal transmission owing to separation of solder joints and solder openings.

Another objective of the present invention is to provide a surface-mount-enhanced lead frame and a method for fabricating a semiconductor package without increasing the semiconductor package area while efficiently increasing the soldering area of the lead frame and the solder paste, so as to enhance the surface wettability of the lead frame.

A further objective of the present invention is to provide a surface-mount-enhanced lead frame and a method for fabricating a semiconductor package that efficiently increases the soldering area of the lead frame and the solder paste, and enhances the surface wettability of the lead frame without requiring special mold for bending the exposed leads.

To achieve the above and other objectives, the surface-mount-enhanced lead frame of the present invention is provided, which comprises: a die pad and a plurality of leads disposed around the die pad, wherein a dam bar structure formed with an indentation is formed to be connected to each end of the leads away from the die pad to allow increased wetting surface between the indentation and the solder metal layer at the bottom of the lead frame.

The semiconductor package that utilizes the said surface-mount-enhanced lead frame comprises: a lead frame comprising a die pad and a plurality of leads disposed around the die pad, wherein a dam bar structure formed with an indentation is formed to be connected to each end of the leads away from the die pad; at least a semiconductor chip bonded to the die pad, and electrically connected to the leads; and a package body covering the semiconductor chip and the lead frame in a manner that the indentation of the dam bar structure is exposed to the ambient.

The manufacturing processes of the semiconductor package with the previously disclosed lead frame comprises the steps of: firstly preparing a lead frame module plate which constitutes a plurality of lead frames arrange in matrix-form, wherein any two neighboring lead frames are separated by dam bar structure formed with an indentation, and wherein the lead frame is formed with a die pad and a plurality of leads disposed around the die pad, allowing the dam bar structure to be connected to ends of the leads away from the die pad; bonding at least a semiconductor chip on each of the die pad of lead frames; forming a plurality of conductive components to electrically connect the semiconductor chip to the corresponding leads; forming a package body on the lead frame module plate to cover the lead frames, semiconductor chips, and the conductive components; and performing a singulation process along the indentation to form the semiconductor packages.

Through the surface-mount-enhanced lead frame of the present invention and the method of fabricating the semiconductor package, using simple fabricating methods, an indentation is formed within the dam bar structure separating neighboring lead frames, so that when in the subsequent singulation process of separating individual semiconductor package with lead frame, the indentation of the dam bar connecting the end of the lead is cut into a first indentation and a second indentation respectively, along the per-determined cutting region between neighboring lead frames. After singulation, it allows the indentation of the same dam bar structure shared by the neighboring lead frames sharing to be connected to the exposed end of the leads, such that when the semiconductor package with the lead frame utilizing the surface-mount-technology is mounted onto an external device, such as a printed circuit board, well wettability and greater soldering areas can be provided to achieve an increase in the soldering area of the solder paste of the lead frame, and signal transmission problems due to separation of the solder joints and solder openings can be greatly reduced by indentation of the dam bar structure at the exposed end of leads. At the same time, under the circumstances that the semiconductor package area is not increased, the soldering area of the solder paste of the lead frame is effectively increased to enhance the surface-mount effect of the semiconductor package with the lead frame.

### BRIEF DESCRIPTION OF THE DRAWINGS

FIG. 1A and FIG. 1B (PRIOR ART) are cross-sectional schematic diagrams of the conventional QFN semiconductor package;

FIG. 2 (PRIOR ART) is a cross-sectional schematic diagram of the QFN semiconductor package of U.S. Pat. No. 6,455,356;

FIG. 3A and FIG. 3B show a top view the surface-mount-enhanced lead frame of the present invention and its cross-sectional view;

FIG. 4A and FIG. 4B show a top view and a cross-sectional schematic view of the surface-mount-enhanced lead frame of the present invention;

FIG. 5 shows a top view of chip bonding and wire soldering processes performed on the lead frames of FIG. 4A and FIG. 4B;

FIG. 6A and FIG. 6B show a top view and a cross-sectional view of the molding process performed on the semiconductor structure of FIG. 5;

FIG. 7A shows a cross-sectional schematic view of the singulation process performed on the semiconductor package structures of FIG. 6A and FIG. 6B;

FIG. 7B to FIG. 7D show top views of the singulation process performed on the semiconductor package structures of FIG. 6A and FIG. 6B; and

FIG. 8 shows a cross-sectional view of the semiconductor package soldering to an external device after singulation has completed.

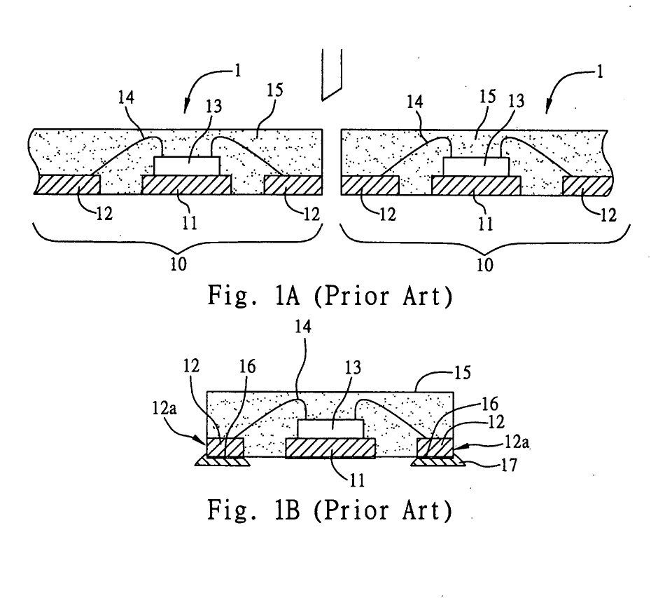

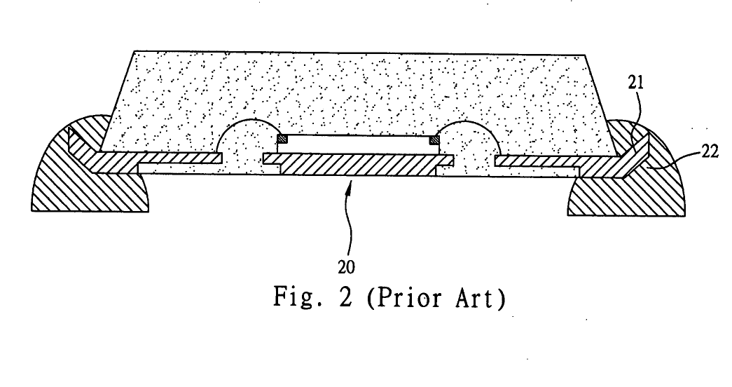

### DETAILED DESCRIPTION OF THE PREFFERED EMBODIMENT

Lead frame suitable for quad-flat non-leaded (QFN) package is disclosed in detail in the embodiments of the present invention below. The embodiments of the present invention are provided to illustrate the lead frame suitable for QFN package, thought the lead frame disclosed in the present invention is not limited to this.

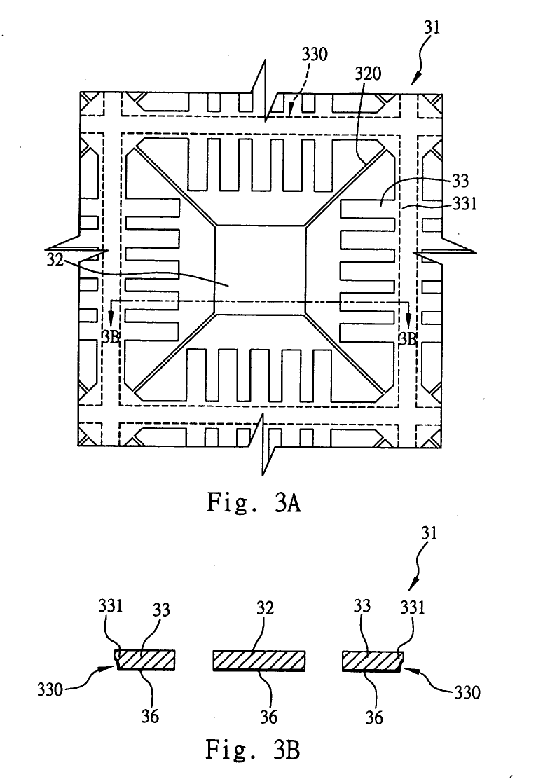

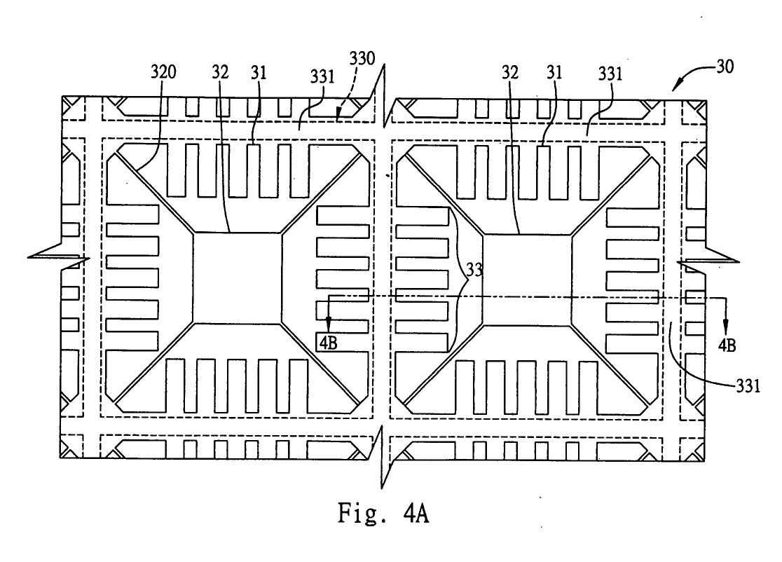

Referring to FIG. 3A and FIG. 3B, they are the schematics of the surface-mount-enhanced lead frame of the present invention, however these diagrams are simplified schematics illustratively showing the structural units related to the present invention, the actual lead frame and the semiconductor package layout are more complicated.

The surface-mount-enhanced lead frame 31 of the present invention consists mainly of a die pad 32 and a plurality of leads 33 distributed around the die pad 32, and a dam bar structure 331 formed with an indentation 330 is connected to the end of the leads 33 away from the die pad 32.

The die pad 32 is connected to the lead frame 31 via a plurality of joint shaft 320, and a solder metal layer 36, for example, a palladium or tin/lead alloy, can be covered on the bottom side of the lead frame 31, so as to allow the lead frame 31 employing the surface-mount-technology (SMT) to be mounted onto external devices, such as printed circuit boards. Through indentation 330 and the solder metal layer 36, good wettability and larger solder area can be provided to enhance the surface-mounting effects.

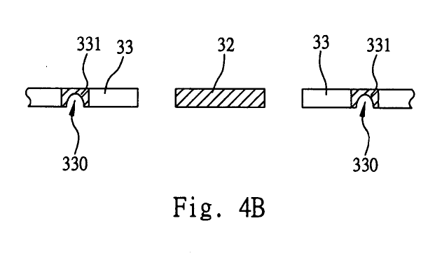

Referring to FIG. 4 to FIG. 7 for a detailed description of the fabrication processes of the semiconductor package with the said lead frame of the present invention.

As shown in FIG. 4A and FIG. 4B, firstly, a lead frame module plate 30 is prepared by method of chemical etching or punching etc. to form a plurality of matrix-form arranged lead frame 31, every neighboring lead frame 31 is separated by a plurality of dam bar structure 331, and which an indentation 330 is formed within, and every lead frame 31 has a die pad 32 and a plurality of leads 33 distributed around the edges of the die pad 32, were the leads 33 are connected to the dam bar structure 331, such that a plurality of package regions are surrounded by of the dam bar structures 331 defined on every lead frame 31. Only two lead frames are illustrated in the Figs., but actually the number of individual lead frames comprising the lead frame module plate is more than that.

The lead frame 31 has a die pad 32 at the center location thereof, and a plurality of leads 33 extending from edges of the lead frame 31 to the center and surrounding the die pad 32, the die pad 32 connects to the lead frame 31 via a plurality of joint shaft 320.

During the process of manufacturing lead frame module plate 30, a mask with opening can be provided in advance on a surface of the lead frame module plate 30, and when in subsequent etching of forming the die pad 32 and leads 33, the indentation can be formed simultaneously on the predetermined dam bar structure 331, or the indentation 330 can be formed by punching method on the dam bar structure 331 of the lead frame module plate 30, the form of the indentation 330 is not limited to the arc curved surface shown in the Figs., but any structure with indentation may be applied to the present invention. Further, since the lead frame module plate 30 is made of copper or iron-nickel alloy material, to effectively solder the lead frame 31 to external device in subsequent processes, a solder metal layer, such as a palladium (Pd) can be formed in advance on the bottom surface of the lead frame module plate 30.

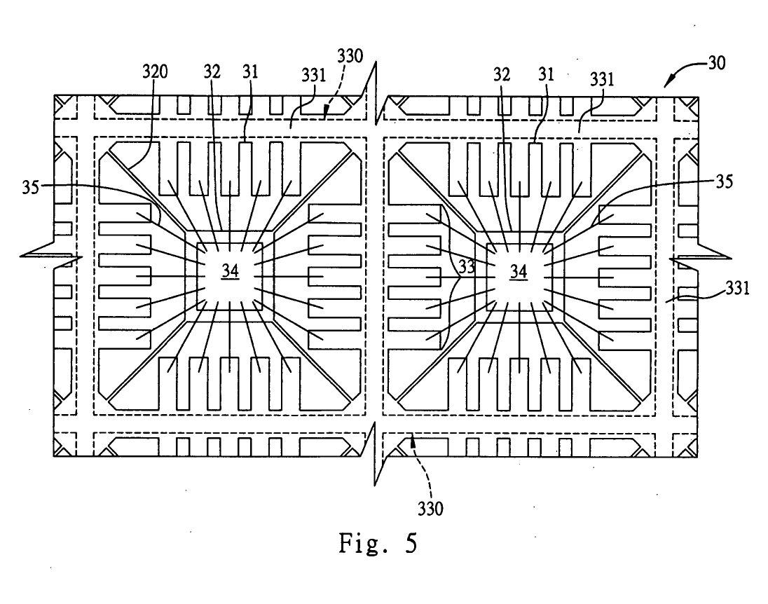

As shown in FIG. 5, after the said lead frame module plate 30 has been fabricated, die bonding process is then performed to bond at least a semiconductor chip 32 on the die pad 32 of the lead frame 31; and next, wire bonding process is performed to form a plurality of wires, such as gold wires, on the lead frame 31, so that the semiconductor chip 34 can electrically connect the corresponding leads 33 via wires 35.

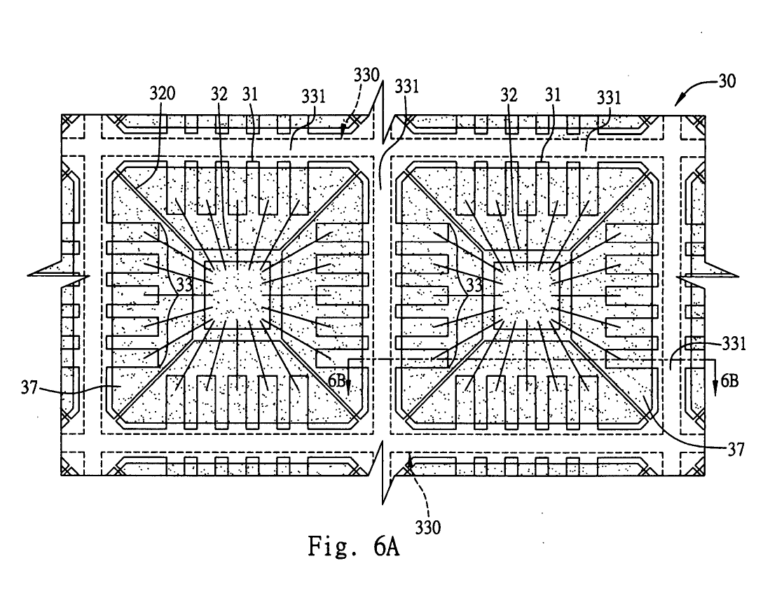

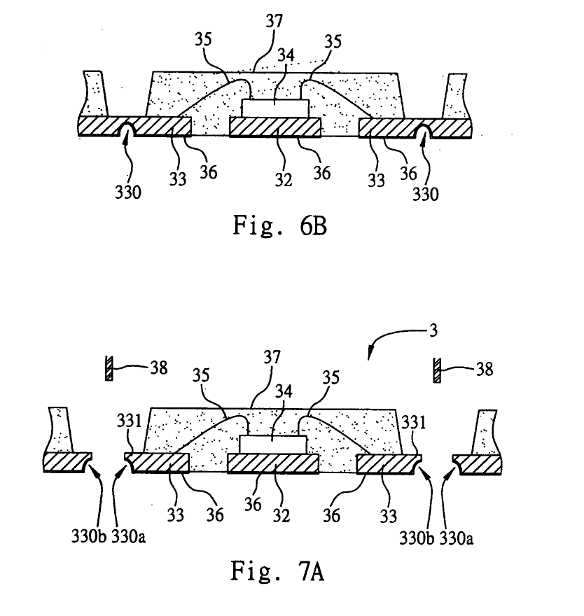

As shown in FIG. 6A and FIG. 6B, a molding process is further performed, a plastic package body 37 formed on every lead frame 31 by epoxy resin is used to cover the semiconductor chip 34, wires 35, and the upper surface of lead frame 31, but the indentation 330 of the dam bar structure outside the plastic package body 37 is exposed. In addition, after the formation of the plastic package body 37, a solder metal layer 36, such as tin/lead (Sn/Pb) alloy can also be formed on the lower surface of the lead frame module plate 30, so as to provide well wettability between the lead frame 31 and the solder paste.

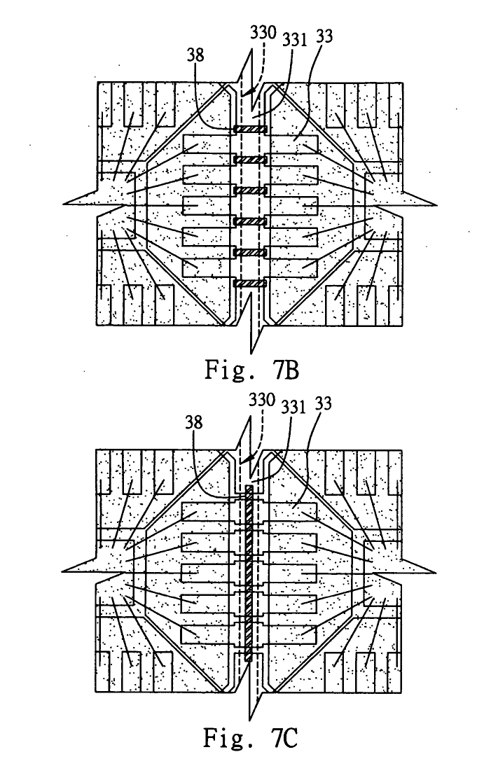

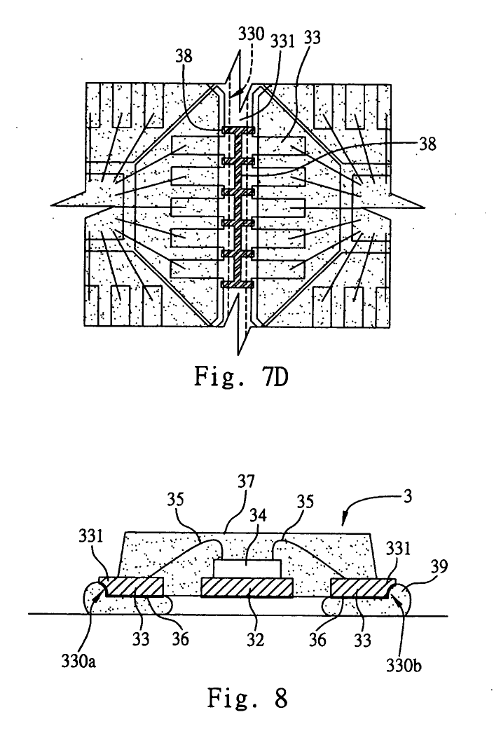

As shown in FIG. 7A, after that, the singulation process is performed, the lead frame module plate 30 is cut along the predetermined cutting region between the dam bar structures 331 of the neighboring lead frames 331. The process is to place the lead frame 30 built with a plurality of packaged QFN semiconductor packages into a machine (not shown) with a plurality of punching cutting tools 38 to perform punching process. Referring to FIGS. 7B and 7C, the punching process uses the punching cutting tools 38 to perform punching in the vertical direction of the respective dam bar structures 331 to separate neighboring leads 33, and punching is performed in the horizontal direction of the dam bar structure 331, the range of punching in horizontal direction should be smaller than the indentation 330 of the dam bar structure 331 to separate the leads 33 connected with the dam bar structure 331. Referring to FIG. 7D, of course, a branched punching tool 38 can be used directly to simultaneously perform punching in the vertical and horizontal direction in order to separate the leads 33 of the lead frames at the same time. By singulation process, the indentation 330 of the dam bar structure 331 is cut to form a corresponding first indentation 330a and a second indentation 330b, enabling the end of leads 33 of the separated QFN semiconductor package 3 with lead frame connected to a dam bar structure 331 with indentations 330a and 330b, as shown in FIG. 7A.

Referring to FIG. 8, using the surface-mount-enhanced lead frame and the method of fabricating the semiconductor package, a QFN semiconductor package 3 with lead frame is provided, wherein the end of the exposed leads 33 is connected to a dam bar structure 331 with a first indentation 330a and a second indentation 330b, and the surfaces of the first indentation 330a and the second indentation 330b are still covered by a solder metal layer 36 to allow the semiconductor package 3 with the lead frame 31 employing the surface-mount-technology (SMT) to be mounted onto an external device, such as a printed circuit board. Through the surfaces of the first indentation 330a and the second indentation 330b of the dam bar and the solder metal layer 36 covered thereon, well wettability and greater soldering areas can be provided to achieve an increase in the soldering area of the solder paste, and signal transmission problems due to separation of the solder joints and solder openings can be greatly reduced. At the same time, under the circumstances that the semiconductor package area is not increased, this enhances the surface-mount effect of the semiconductor package with the lead frame.

The foregoing embodiments were chosen and described in order to best explain the principles of the invention and its practical application, it is not intended to limit the scope of the present invention in any way, and to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A surface-mount-enhanced lead frame, comprising:
a die pad; and
a plurality of leads disposed around the die pad, wherein a dam bar structure formed with an indentation is integrally formed to be connected to each end of the leads away from the die pad.

2. The lead frame as claimed in claim 1, wherein the lead frame is a quad-flat non-leaded (QFN) lead frame.

3. The lead frame as claimed in claim 1, wherein the indentation is formed by either one of the chemical etching or punching method.

4. The lead frame as claimed in claim 1, wherein a solder metal layer is further formed on the surface of the indentation of the dam bar structure of the lead frame.

5. The lead frame as claimed in claim 4, wherein the solder metal layer is made of metal palladium (Pd) and is pre-plated on a surface of the lead frame.

6. The lead frame as claimed in claim 4, wherein the solder metal layer made of tin/lead (Sn/Pb) covers an exposed surface of the lead frame after a molding process is conducted to form a package body coupled to the lead frame.

7. A semiconductor package with a surface-mount-enhanced lead frame, comprising:
a lead frame comprising a die pad and a plurality of leads disposed around the die pad, and a dam bar structure formed with an indentation is integrally formed to be connected to each end of the leads away from the die pad;
at least a semiconductor chip bonded on the die pad, and electrically connected to the leads; and
a package body formed to encapsulate the semiconductor chip and the lead frame in a manner that the indentation of the dam bar structure is exposed to the ambient.

8. The semiconductor package as claimed in claim 7, wherein the lead frame is a quad-flat non-leaded (QFN) lead frame.

9. The semiconductor package as claimed in claim 7, wherein the indentation is formed by either one of the chemical etching or punching method.

10. The semiconductor package as claimed in claim 7, wherein a solder metal layer is formed on a surface of the indentation of the dam bar structure of the lead frame.

11. The semiconductor package as claimed in claim 10, wherein the solder metal layer is made of metal palladium (Pd) which is pre-plated on a surface of the lead frame.

12. The semiconductor package as claimed in claim 10, wherein the solder metal layer made of tin/lead (Sn/Pb) covers an exposed surface of the lead frame after a molding process is conducted to form a package body coupled to the lead frame.

13. A method for fabricating a semiconductor package with surface-mount-enhanced lead frame, comprising:
preparing a lead frame module plate which consists of a plurality of lead frames arranged in matrix form, wherein any two of the neighboring lead frames are separated by a dam bar structure formed with an indentation, and wherein the lead frame comprises a die pad and a plurality of leads disposed around the die pad in a manner that ends of the leads oriented away from the die pad are connected to the dam bar structure;
bonding at least a semiconductor chip on the die pad of each of the lead frame;
electrically connecting the semiconductor chip to the corresponding leads;
forming a package body on the lead frame module plate to cover the lead frames and the semiconductor chips, in a manner that each of the indentations of the dam bar structures is exposed to the ambient; and
performing a singulation process along the indentations of the dam bar structures so as to separate the lead frame module plate mounted with the semiconductor chips and package body into a plurality of semiconductor packages.

14. The method as claimed in claim 13, wherein the lead frame is a quad-flat non-leaded (QFN) lead frame.

15. The method as claimed in claim 13, wherein the indentation is formed by either one of the chemical etching or punching method.

16. The method for fabricating the semiconductor as claimed in claim 13, wherein a solder metal layer is formed on a surface of each of the indentations of the dam bar structures on the lead frame module plate.

17. The method as claimed in claim 16, wherein the solder metal layer made of metal palladium (Pd) is pre-plated on a surface of the lead frame module plate.

18. The method as claimed in claim 16, wherein the solder metal layer made of tin/lead (Sn/Pb) covers an exposed surface of the lead frame module plate after a molding process is conducted to form the package body coupled to the lead frame module plate.

19. The method as claimed in claim 13, wherein the singulation process is a punching process.

20. The method as claimed in claim 13, wherein a branched punching cutting tool is used for performing the singulation process.
